(19) United States
(12) Patent Application Publication
(10) Pub. No.: US 2025/0294700 A1
(43) Pub. Date: Sep. 18, 2025

(54) ELECTRONIC DEVICE RACK, ELECTRONIC DEVICE UNIT, AND METHOD OF INSTALLING ELECTRONIC DEVICE RACK

(71) Applicant: NEC Corporation, Tokyo (JP)

(72) Inventor: Satoshi HIRAO, Tokyo (JP)

(73) Assignee: NEC Corporation, Tokyo (JP)

(21) Appl. No.: 19/010,633

(22) Filed: Jan. 6, 2025

(30) Foreign Application Priority Data
Mar. 14, 2024 (JP) 2024-040035

(51) Int. Cl. H05K 7/18

(52) U.S. Cl. CPC H05K 7/18

(57) ABSTRACT

An electronic device rack includes a bottom plate portion, a top plate portion spaced apart from the bottom plate portion in a vertical direction, a pair of expanders between the bottom plate portion and the top plate portion, the pair of expanders being spaced apart from each other in a width direction, each expander being configured to individually expand in the vertical direction to be in an expanded state, and a constraint portion provided between the bottom plate portion and the top plate portion and configured to constrain the pair of expanders in the expanded state.

### CROSS-REFERENCE TO RELATED APPLICATION

Priority is claimed on Japanese Patent Application No. 2024-040035, filed Mar. 14, 2024, the content of which is incorporated herein by reference.

### BACKGROUND ART

The present disclosure relates to an electronic device rack, an electronic device unit, and a method of installing an electronic device rack.

A rack in which electronic devices are housed is widely known.

For example, a server rack that houses a main computer or a memory device is described in Japanese Unexamined Patent Application, First Publication No. 2005-163872 (hereinafter referred to as Patent Document 1).

### SUMMARY

In a case where an electronic device rack such as the server rack described in Patent Document 1 houses a plurality of electronic devices, the electronic device rack is likely to have a large size according to the size or the number of the housed electronic devices. In a case where the size of the electronic device rack increases, carrying of the electronic device rack into a room in which the electronic device rack is installed in a building may be difficult according to the size of a doorway to the room.

An example objective of the present disclosure is to provide an electronic device rack, an electronic device unit, and a method of installing an electronic device rack that can solve the aforementioned problem.

An electronic device rack according to an example aspect of the present disclosure includes: a bottom plate portion; a top plate portion spaced apart from the bottom plate portion in a vertical direction; a pair of expanders between the bottom plate portion and the top plate portion, the pair of expanders being spaced apart from each other in a width direction, each expander being configured to individually expand in the vertical direction to be in an expanded state; and a constraint portion provided between the bottom plate portion and the top plate portion and configured to constrain the pair of expanders in the expanded state.

A method of installing an electronic device rack according to another example aspect of the present disclosure includes: switching an electronic device rack to a contracted state by contracting a pair of expanders between a bottom plate portion and a top plate portion of the electronic device rack to make the bottom plate portion and the top plate portion approach each other, the electronic device rack being configured such that an electronic instrument is mounted in the electronic device rack, the pair of expanders being spaced apart from each other in a width direction, the top plate portion being spaced apart from the bottom plate portion in a vertical direction; carrying the electronic device rack in the contracted state into an installation place of the electronic device rack; and switching the electronic device rack to an expanded state by expanding the pair of expanders to separate the bottom plate portion and the top plate portion from each other to install the electronic device rack in the installation place.

### BRIEF DESCRIPTION OF THE DRAWINGS

FIG. 1 is a perspective view illustrating an electronic device unit according to the present disclosure.

FIG. 2 is a perspective view illustrating an intermediate state between an expanded state and a contracted state of the electronic device unit according to the present disclosure.

FIG. 3 is a perspective view illustrating a contracted state of the electronic device unit according to the present disclosure.

FIG. 4 is a perspective view illustrating a plate-shaped member according to the present disclosure.

FIG. 5 is a perspective view illustrating a state in which a connection pin of one plate-shaped member is inserted into an insertion hole of the other plate-shaped member in a state in which the electronic device rack according to the present disclosure is expanded.

FIG. 6 is a perspective view illustrating a state in which a connection pin of one plate-shaped member is inserted into an insertion hole of the other plate-shaped member in a state in which the electronic device rack according to the present disclosure is contracted.

FIG. 7 is a diagram illustrating a flow of a method of installing an electronic device rack according to the present disclosure.

FIG. 8 is a diagram illustrating the electronic device rack according to the present disclosure.

FIG. 9 is a diagram illustrating an electronic device according to the present disclosure.

FIG. 10 is a diagram illustrating a flow of the method of installing the electronic device rack according to the present disclosure.

### EXAMPLE EMBODIMENT

Hereinafter, example embodiments will be described with reference to the accompanying drawings. The same or corresponding elements in all the drawings will be referred to as by the same reference signs, and a repeated description thereof will be omitted.

The drawings according to the present disclosure are associated with one or more example embodiments.

Some example embodiments of the present disclosure will be described below with reference to the drawings.

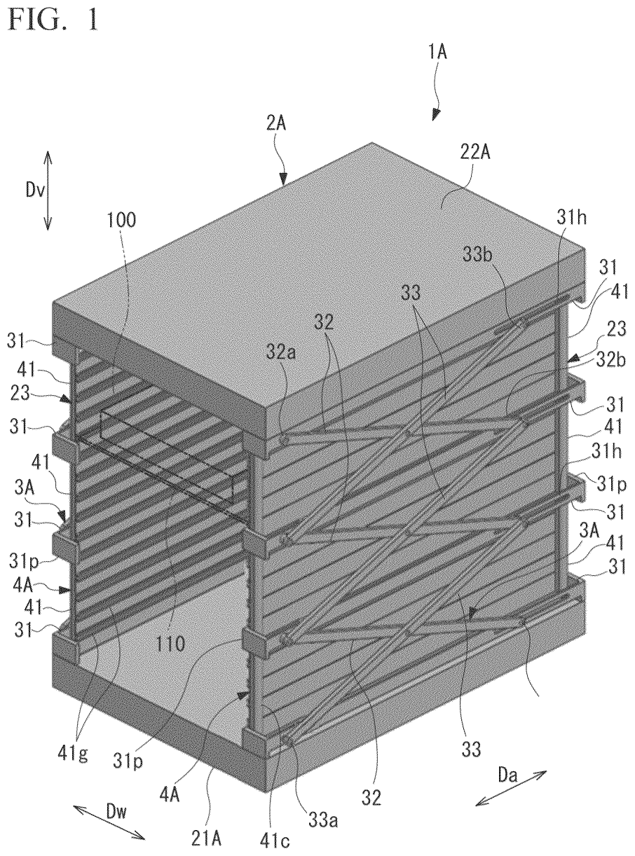

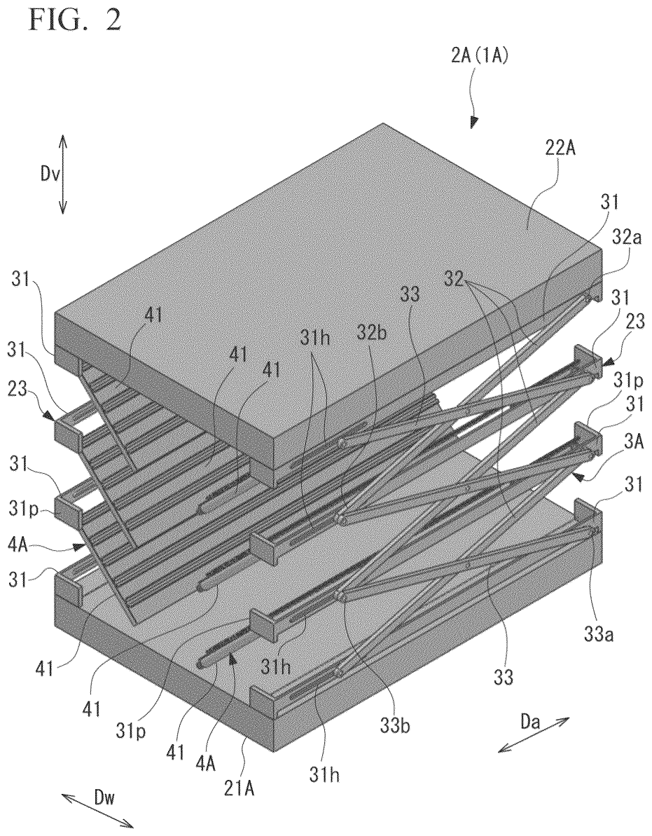

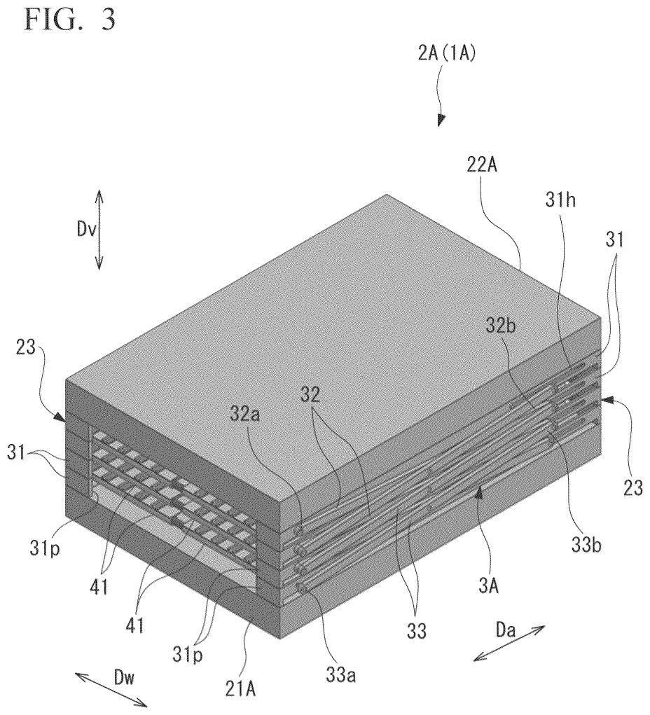

FIG. 1 is a perspective view illustrating an electronic device unit 1A according to the present disclosure. FIG. 2 is a perspective view illustrating an intermediate state between an expanded state and a contracted state of the electronic device unit 1A according to the present disclosure. FIG. 3 is a perspective view illustrating a contracted state of the electronic device unit 1A according to the present disclosure.

As illustrated in FIG. 1, the electronic device unit 1 Aincludes an electronic device rack 2A and an electronic device (an electronic instrument) 100 mounted on the electronic device rack 2A.

As illustrated in FIGS. 1 to 3, the electronic device rack 2A includes a bottom plate portion 21A, a top plate portion 22A, and a pair of side wall portions 23.

The bottom plate portion 21A is installed on a floor surface of an installation place of the electronic device rack 2A. The bottom plate portion 21A has a rectangular shape as seen in a vertical direction Dv. The bottom plate portion 21A has a plate shape extending along a plane crossing the vertical direction Dv. The bottom plate portion 21A may include casters or leg members extending downward and coming into contact with the floor surface.

The top plate portion 22A is provided above the bottom plate portion 21A with a gap therebetween. The top plate portion 22A is formed in a rectangular shape as seen in the vertical direction Dv. The top plate portion 22A is provided to overlap the bottom plate portion 21A as seen in the vertical direction Dv.

In the following description, a short-side direction of the bottom plate portion 21A and the top plate portion 22A which are rectangular is defined as a width direction Dw. Along-side direction of the bottom plate portion 21A and the top plate portion 22A is defined as a longitudinal direction Da.

A pair of side wall portions 23 is provided between the bottom plate portion 21A and the top plate portion 22A in the vertical direction Dv. The pair of side wall portions 23 is provided at both ends in the width direction Dw between the bottom plate portion 21A and the top plate portion 22A.

Each of the pair off side wall portions 23 includes an expanding and contracting mechanism (an expander) 3A and a constraint portion 4A.

The expanding and contracting mechanism 3A is provided between the bottom plate portion 21A and the top plate portion 22A. The expanding and contracting mechanism 3A is configured to expandable and contractible in the vertical direction Dv.

The expanding and contracting mechanism 3A expands and contracts in the vertical direction Dv to cause the bottom plate portion 21A and the top plate portion 22A to approach each other and be separated in the vertical direction Dv.

The expanding and contracting mechanism 3A has a so-called pantograph shape.

The expanding and contracting mechanism 3A includes a plurality of support members 31, a plurality of sets of a first link member 32 and a second link member 33.

As long as the expanding and contracting mechanism 3A can expand and contract in the vertical direction Dv to cause the bottom plate portion 21A and the top plate portion 22A to approach each other and be separated in the vertical direction Dv, the expanding and contracting mechanism 3A not limited to a pantograph shape and can be appropriately changed to another configuration such as a foldable type or a telescopic type.

The plurality of support members 31 are proved with a gap therebetween in the vertical direction Dv. In the present disclosure, for example, four support members 31 are provided with a gap therebetween in the vertical direction Dv. The number of support members 31 is not limited to four and may be two, three, or five or more. The lowest support member 31 out of the plurality of support members 31 is attached to the top of both ends in the width direction Dw of the bottom plate portion 21A. The highest support member 31 out of the plurality of support members 31 is attached to the bottom of both ends in the width direction Dw of the top plate portion 22A.

Each support member 31 extends in the longitudinal direction Da. Each support member 31 includes a shaft support hole (not illustrated) at a first end in the longitudinal direction Da. The shaft support hole penetrates the support member 31 in the width direction Dw. Each support member 31 includes a slide hole 31h at a second end in the longitudinal direction Da. The slide hole 31h penetrates the support member 31 in the width direction Dw and extends in the longitudinal direction Da. A support plate 3ip protruding inward in the width direction Dw is provided at both ends in the longitudinal direction Da of each support member 31.

The plurality of sets of the first link member 32 and the second link member 33 are provided between the support members 31 located above and below. In the present disclosure, for example, three sets of the first link member 32 and the second link member 33 are provided in the vertical direction Dv.

A first end 32a of the first link member 32 in each set is supported to be rotatable by the shaft support hole (not illustrated) of one of the support members 31 located above and below. A second end 32b of the first link member 32 in each set is supported to be slidable in the longitudinal direction Da by the slide hole 31h of the other of the support members 31 located above and below. In the present disclosure, a first end 32a of the first link member 32 is supported to be rotatable by the shaft support hole (not illustrated) of the support member 31 located above. In the present disclosure, the second end 32b of the first link member 32 is supported to be slidable in the longitudinal direction Da by the slide hole 31h of the support member 31 located below.

A first end 33a of the second link member 33 in each set is supported to be rotatable by the shaft support hole (not illustrated) of the other of the support members 31 located above and below. A second end 33b of the second link member 33 in each set is supported to be slidable in the longitudinal direction Da by the slide hole 31h of the one of the support members 31 located above and below. In the present disclosure, the first end 33a of the second link member 33 is supported to be rotatable by the shaft support hole (not illustrated) of the support member 31 located below. In the present disclosure, the second end 33b of the second link member 33 is supported to be slidable in the longitudinal direction Da by the slide hole 31h of the support member 31 located above.

The first end 32a of the first link member 32 and the first end 33a of the second link member 33 which are supported by the same shaft support hole are provided to be coaxial. The second end 32b of the first link member 32 and the second end 33b of the second link member 33 which are supported by the same slide hole 31h are provided to be coaxial. A central part of the first link member 32 and a central part of the second link member 33 in each set are connected to be relatively rotatable.

This expanding and contracting mechanism 3A expands and contracts in the vertical direction Dv in a case where the first link member 32 and the second link member 33 in each of the plurality of sets rotate about the first ends 32a and 33a and the second ends 32b and 33b slide along the slide holes 31h. The expanding and contracting operation of the expanding and contracting mechanism 3A is performed, for example, by allowing an operator to raise and lower the top plate portion 22A with respect to the bottom plate portion 21A. For example, a hydraulic jack may be used to raise and lower the top plate portion 22A with respect to the bottom plate portion 21A.

The expanding and contracting mechanism 3A enters an area in which the top plate portion 22A and the bottom plate portion 21A overlap, that is, an inner area of the electronic device rack 2A, as seen from above in the contracted state.

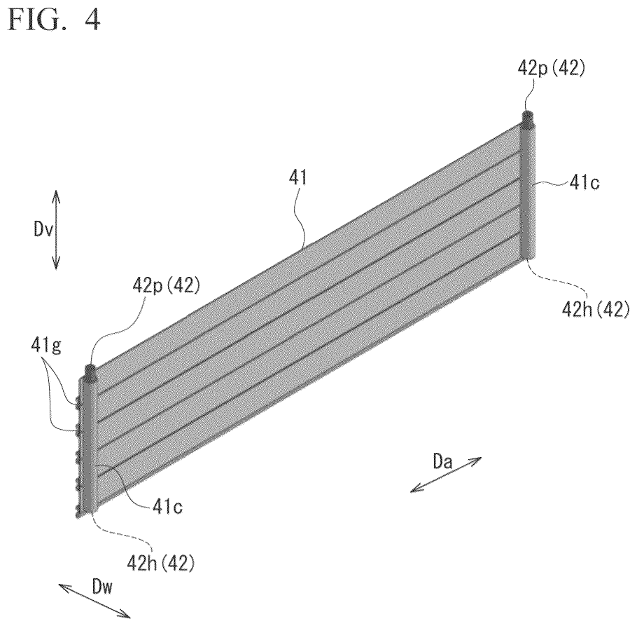

The constraint portion 4A is provided between the bottom plate portion 21A and the top plate portion 22A. The constraint portion 4A can constrain a pair of expanding and contracting mechanisms 3A at both ends in the width direction Dw in the expanded state as illustrated in FIG. 1. The constraint portion 4A is provided at both ends in the width direction Dw. In the present disclosure, the constraint portion 4A includes a plate-shaped member 41 and a fixing portion 42 (see FIG. 4).

A plurality of plate-shaped members 41 are provided side by side in the vertical direction Dv. In the present disclosure, for example, three plate-shaped members 41 are provided side by side in the vertical direction Dv. The plurality of plate-shaped members 41 are provided inside of the expanding and contracting mechanisms 3A at both ends in the width direction Dw in the width direction Dw.

One of an upper end and a lower end of each plate-shaped member 41 is supported to be rotatable about an axial direction extending in the longitudinal direction Da by the corresponding support member 31. In the present disclosure, the upper end of each plate-shaped member 41 is supported to be rotatable in the axial direction extending in the longitudinal direction Da. In the present disclosure, both ends in the longitudinal direction Da of the upper end of each plate-shaped member 41 is supported to be rotatable about the axial direction extending in the longitudinal direction Da by the support plats 3ip provided at each of both ends in the longitudinal direction Da of the support member 31.

In a state in which the expanding and contracting mechanism 3A is expanded to vertically separate the bottom plate portion 21A and the top plate portion 22A and the electronic device rack 2A is expanded as illustrated in FIG. 1, each plate-shaped member 41 rises up along a plane crossing the width direction Dw. In this state, each of the plurality of plate-shaped members 41 is stacked in the vertical direction, and thus the bottom plate portion 21A and the top plate portion 22A are constrained in a state in which they are separated with a predetermined interval in the vertical direction Dv.

In a state in which the expanding and contracting mechanism 3A is contracted to cause the bottom plate portion 21A and the top plate portion 22A to approach each other in the vertical direction and the electronic device rack 2A is contracted as illustrated in FIG. 3, each plate-shaped member 41 falls along a plane crossing the vertical direction Dv.

The lower end of each plate-shaped member 41 may be supported to be rotatable by the corresponding support member 31. Here, in a case where the upper end of each plate-shaped member 41 is supported to be rotatable by the support member 31, each plate-shaped member 41 can be made to rise up with the weight of the plate-shaped member 41 from a state in which the plate-shaped member 41 is parallel to the horizontal plane at the time of switching the electronic device rack 2A from the contracted state to the expanded state as illustrated in FIG. 2.

FIG. 4 is a perspective view illustrating a plate-shaped member 41 according to the present disclosure.

As illustrated in FIG. 4, each plate-shaped member 41 includes a columnar portion 41c extending in the vertical direction Dv at both ends in the longitudinal direction Da.

The fixing portion 42 is provided in the columnar portions 41c at both ends in the longitudinal direction Da of each plate-shaped member 41. The fixing portion 42 fixes the plurality of plate-shaped members 41 in a state in which it is parallel to a plane including the vertical direction Dv. The fixing portion 42 connects the plate-shaped members 41 located above and below. The fixing portion 42 includes a connection pin 42p and an insertion hole 42h.

The connection pin 42p is provided at one of the upper end and the lower of the plate-shaped member 41. The connection pin 42p protrudes to another plate-shaped member 41 located above or below. In the plate-shaped member 41 at a first end in the width direction Dw in the present disclosure, the connection pin 42p is provided to protrude downward form the lower end of the columnar portion 41c. In the plate-shaped member 41 at a second end in the width direction Dw in the present disclosure, the connection pin 42p is provided to protrude upward from the upper end of the columnar portion 41c.

The insertion hole 42h is provided at the other of the upper end and the lower end of the plate-shaped member 41. The connection pin 42p of another plate-shaped member 41 located vertically can be inserted into the insertion hole 42h. In the plate-shaped member 41 at a first end in the width direction Dw in the present disclosure, the insertion hole 42h is provided to be recessed downward from the upper end of the columnar portion 41c. In the plate-shaped member 41 at a second end in the width direction Dw in the present disclosure, the insertion hole 42h is provided to be recessed upward from the lower end of the columnar portion 41c.

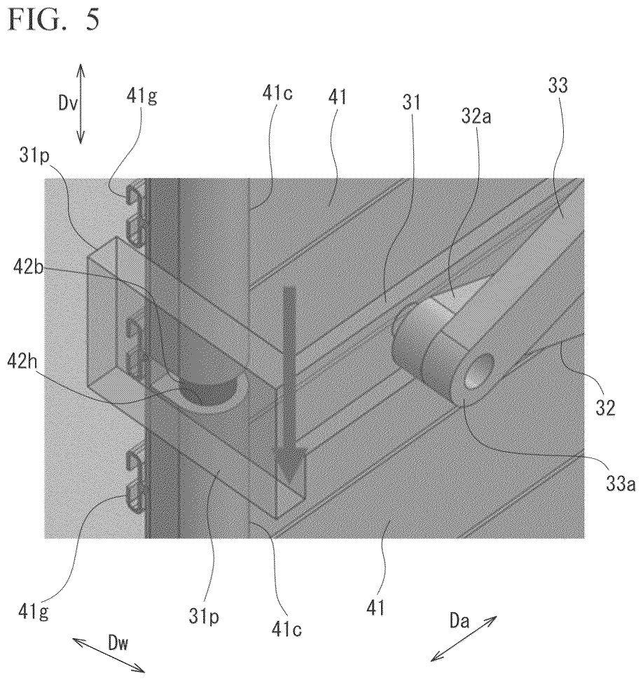

FIG. 5 is a perspective view illustrating a state in which the connection pin of one plate-shaped member is inserted into an insertion hole of the other plate-shaped member in a state in which the electronic device rack according to the present disclosure is expanded.

In the state in which the electronic device rack 2A has been expanded as illustrated in FIG. 5, the connection pin 42p of one plate-shaped member 41 out of the plate-shaped members 41 located above and below is inserted into the insertion hole 42h of the other plate-shaped member 41. Accordingly, the plurality of plate-shaped members 41 rise up along a plane crossing the width direction Dw and are fixed to a state in which they are stacked in the vertical direction.

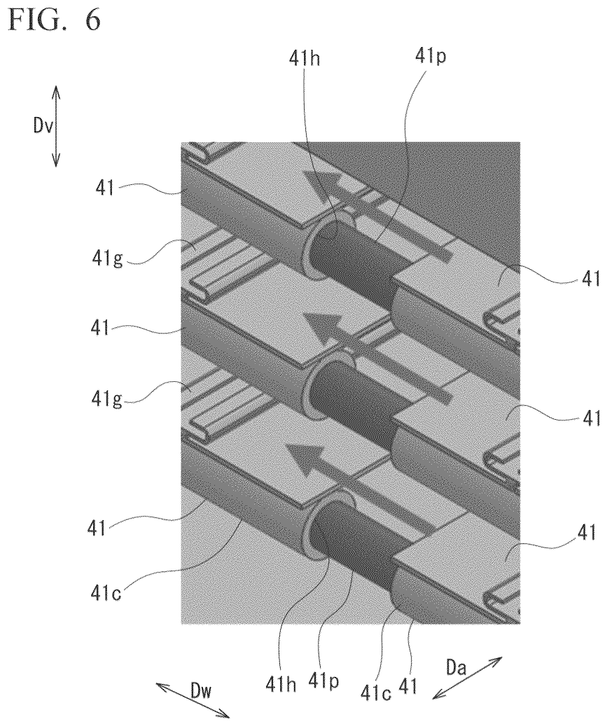

FIG. 6 is a perspective view illustrating a state in which the connection pin of one plate-shaped member is inserted into the insertion hole of the other plate-shaped member in a state in which the electronic device rack according to the present disclosure is contracted.

In the state in which the electronic device rack 2A has been contracted as illustrated in FIG. 6, the connection pin 42p of the plate-shaped member 41 at a first end in the width direction Dw is inserted into the insertion hole 42h of the plate-shaped member 41 at a second end in the width direction Dw. Accordingly, the plate-shaped member 41 at the first end in the width direction Dw and the plate-shaped member 41 at the second end in the width direction Dw are fixed to a state in which they have fallen along a plane crossing the vertical direction Dv.

As illustrated in FIG. 1, each plate-shaped member 41 includes a device support portion 41g on a surface facing inward in the width direction Dw. In the present disclosure, for example, the device support portion 41g is a guide rail extending in the longitudinal direction Da. The device support portion 41g can support an electronic device 100 that is mounted on the electronic device rack 2A. The device support portions 41g can support, for example, both ends in the width direction Dw of a mount member 110 of a plate shape on which an electronic device 100 is mounted. The device support portion 41g may support brackets (not illustrated) provided at both ends in the width direction Dw of the electronic device 100.

Examples of the electronic device 100 supported by the device support portions 41g include a server, a switch device, and a data logger. The electronic device rack 2A may be provided with various interface units for connection of the electronic device 100 mounted thereon or the like.

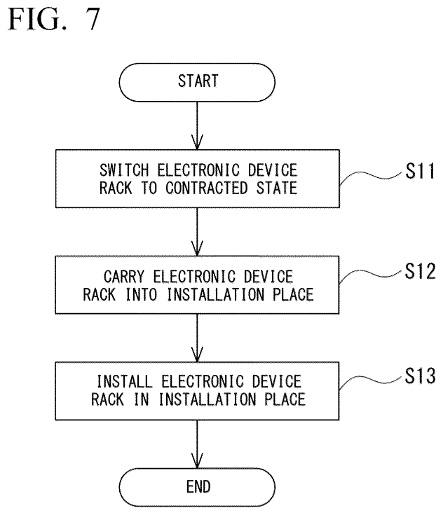

FIG. 7 is a diagram illustrating a flow of a method of installing the electronic device rack 2A according to the present disclosure.

As illustrated in FIG. 7, the method of installing the electronic device rack 2A according to the present disclosure includes a step S11 of switching the electronic device rack 2A to the contracted state, a step S12 of carrying the electronic device rack 2A into an installation place, and a step S13 of installing the electronic device rack 2A in the installation place.

In the step S11 of switching the electronic device rack 2A to the contracted state, the electronic device rack 2A is switched to the contracted state before carrying the electronic device 100 into the installation place as illustrated in FIG. 3. As illustrated in FIG. 2, a pair of expanding and contracting mechanisms 3A between the bottom plate portion 21A and the top plate portion 22A of the electronic device rack 2A is contracted to cause the bottom plate portion 21A and the top plate portion 22A to approach each other. Accordingly, as illustrated in FIG. 3, the plate-shaped members 41 fall and are located along the place crossing the vertical direction Dv. Then, as illustrated in FIG. 6, the connection pins 42p of the plate-shaped members 41 at a first end in the width direction Dw are inserted into the insertion holes 42h of the plate-shaped members 41 at a second end in the width direction Dw. Accordingly, the electronic device rack 2A is switched to the contracted state.

In the step S12 of carrying the electronic device rack 2A into the installation place, the electronic device rack 2A in the contracted state is carried into the installation place of the electronic device rack 2A. At this time, since the electronic device rack 2A is in the contracted state, the electronic device rack 2A can pass a doorway through which the electronic device rack 2A has difficulty passing in the expanded state.

Thereafter, in the step S13 of installing the electronic device rack 2A in the installation place, the pair of expanding and contracting mechanisms 3A is expanded to separate the bottom plate portion 21A and the top plate portion 22A from each other as illustrated in FIGS. 2 and 1. Then, the plate-shaped members 41 rise up. In the state in which the electronic device rack 2A has been expanded, the connection pin 42p of one plate-shaped member 41 out of the plate-shaped members 41 located above and below is inserted into the insertion hole 42h of the other plate-shaped member 41 as illustrated in FIG. 5. Accordingly, as illustrated in FIG. 1, the plurality of plate-shaped members 41 rise up along the plane crossing the width direction Dw and is fixed in a state in which they are stacked in the vertical direction. In this way, the electronic device rack 2A is switched to the expanded state. The electronic device rack 2A is installed in the predetermined installation place.

The electronic device rack 2A according to the example embodiments includes the pair of expanding and contracting mechanisms 3A and the constraint portion 4A that can constrain the pair of expanding and contracting mechanisms 3A in the expanded state. Accordingly, it is possible to switch the electronic device rack 2A to the contracted state by contracting the pair of expanding and contracting mechanisms 3A. As a result, it is possible to easily carry the electronic device rack 2A into the installation place. A plurality of electronic device racks 2A in the contracted state can also be stacked and carried.

After carrying the electronic device rack 2A into the installation place, it is possible to maintain the state in which the electronic device rack 2A is expanded by constraining the pair of expanding and contracting mechanisms 3A in the expanded state using the constraint portion 4A and to stably mount the electronic device 100.

The constraint portion 4A of the electronic device rack 2A according to the example embodiments includes the plate-shaped member 41 and the fixing portion 42 that fixes the plate-shaped member 41 to be parallel to the plane including the vertical direction Dv. Accordingly, in a case where the electronic device rack 2A is expanded, it is possible to constrain the pair of expanding and contracting mechanisms 3A in the expanded state.

The fixing portion 42 of the electronic device rack 2A according to the example embodiments connects the plate-shaped members 41 located above and below. Accordingly, in a case where the electronic device rack 2A is expanded, it is possible to connect the plurality of plate-shaped members 41 and to constrain the pair of expanding and contracting mechanisms 3A in the expanded state.

The fixing portion 42 of the electronic device rack 2A according to the example embodiments connects the plate-shaped member 41 at a first end in the width direction Dw and the plate-shaped member 41 at a second end in the width direction Dw which are parallel to the plane crossing the vertical direction Dv. In a case where the electronic device rack 2A is contracted, it is possible to connect the plate-shaped member 41 at the first end in the width direction Dw and the plate-shaped member 41 at the second end in the width direction Dw to each other.

The constraint portion 4A of the electronic device rack 2A according to the example embodiments is provided inside of the pair of expanding and contracting mechanisms 3A in the width direction Dw. Accordingly, it is possible to construct the side wall portions 23 of the electronic device rack 2A using the pair of expanding and contracting mechanisms 3A and the constraint portion 4A.

Each expanding and contracting mechanism 3A of the electronic device rack 2A according to the example embodiments includes the support member 31, the first link member 32, and the second link member 33. Accordingly, the expanding and contracting mechanism 3A has a so-called pantograph shape and can be easily expanded and contracted in the vertical direction.

In the electronic device rack 2A according to the example embodiments, one of the upper end and the lower end of each plate-shaped member 41 is supported to be rotatable about the axial direction by the support member 31. Accordingly, it is not necessary to provide a particular member for supporting the plate-shaped member 41, and it is possible to provide the expanding and contracting mechanism 3A and the constraint portion 4A while curbing the number of components.

Each plate-shaped member 41 of the electronic device rack 2A according to the example embodiments includes the device support portion 41g. Accordingly, it is possible to mount an electronic device 100 on the electronic device rack 2A.

The electronic device unit 1A according to the example embodiments includes the electronic device rack 2A and an electronic device 100. Accordingly, it is possible to provide an electronic device unit 1A including the electronic device rack 2A which can be easily carried into an installation place.

With the method of installing the electronic device rack 2A according to the example embodiments, it is possible to install the electronic device rack 2A which can be easily carried into an installation place.

Some example embodiments of the present disclosure will be described below with reference to the accompanying drawings.

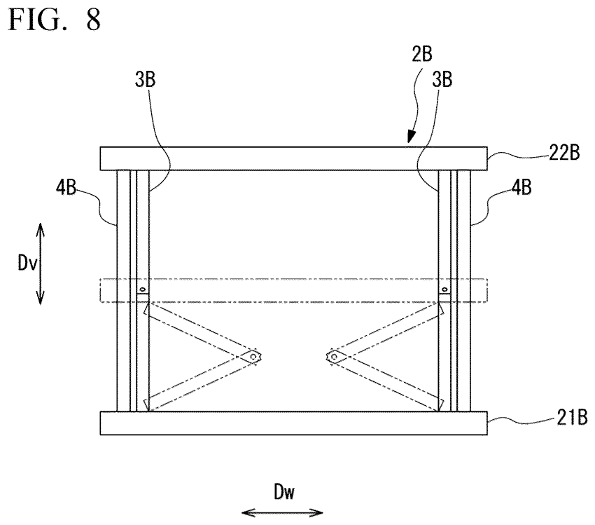

As illustrated in FIG. 8, an electronic device rack 2B according to the present disclosure includes a bottom plate portion 21B, a top plate portion 22B, a pair of expanding and contracting mechanisms 3B, and a constraint portion 4B.

The top plate portion 22B is provided above the bottom plate portion 21B with a gap therebetween.

The pair of expanding and contracting mechanisms 3B is provided between the bottom plate portion 21B and the top plate portion 22B with a gap therebetween in the width direction Dw. The pair of expanding and contracting mechanisms 3B is configured to expand and contract in the vertical direction Dv.

The constraint portion 4B is provided between the bottom plate portion 21B and the top plate portion 22B. The constraint portion 4B can constrain the pair of expanding and contracting mechanism 3B in the expanded state.

The electronic device rack 2B according to the example embodiments includes the pair of expanding and contracting mechanisms 3B and the constraint portion 4B that can constrain the pair of expanding and contracting mechanisms 3B in the expanded state. Accordingly, it is possible to switch the electronic device rack 2B to the contracted state by contracting the pair of expanding and contracting mechanisms 3B. Accordingly, the electronic device rack 2B can be easily carried into an installation place. After carrying the electronic device rack 2B into the installation place, it is possible to maintain the state in which the electronic device rack 2B is expanded by constraining the pair of expanding and contracting mechanisms 3B in the expanded state using the constraint portion 4B and to stably mount an electronic device 100 thereon.

Some example embodiments of the present disclosure will be described below with reference to the accompanying drawings.

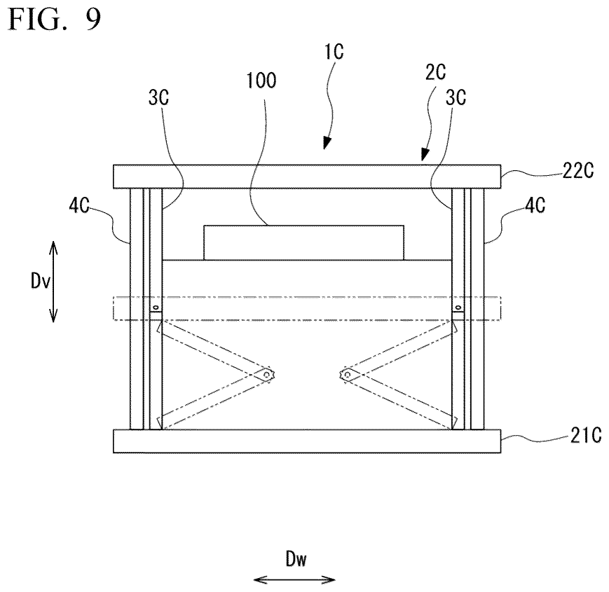

As illustrated in FIG. 9, an electronic device unit 1C according to the present disclosure includes an electronic device rack 2C and an electronic device 100 mounted on the electronic device rack 2C.

The electronic device rack 2C includes a bottom plate portion 21C, a top plate portion 22C, a pair of expanding and contracting mechanisms 3C, and a constraint portion 4C.

The top plate portion 22C is provided above the bottom plate portion 21C with a gap therebetween.

The pair of expanding and contracting mechanisms 3C is provided between the bottom plate portion 21C and the top plate portion 22C with a gap therebetween in the width direction Dw. The pair of expanding and contracting mechanisms 3C is configured to expand and contract in the vertical direction Dv.

The constraint portion 4C is provided between the bottom plate portion 21C and the top plate portion 22C. The constraint portion 4C can constrain the pair of expanding and contracting mechanism 3C in the expanded state.

The electronic device unit 1C according to the example embodiments includes the electronic device rack 2C and an electronic device 100. Accordingly, it is possible to provide an electronic device unit 1C including the electronic device rack 2C which can be easily carried into an installation place.

Some example embodiments of the present disclosure will be described below with reference to the accompanying drawings.

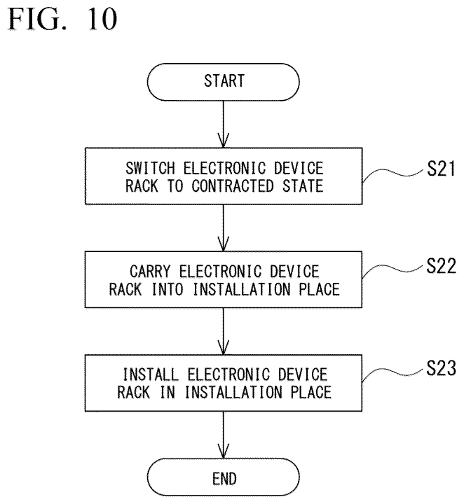

As illustrated in FIG. 10, the method of installing the electronic device rack according to the present disclosure includes a step S21 of switching the electronic device rack to the contracted state, a step S22 of carrying the electronic device rack into an installation place, and a step S23 of installing the electronic device rack in the installation place.

In the step S21 of switching the electronic device rack to the contracted state, a pair of expanding and contracting mechanisms is contracted. The pair of expanding and contracting mechanisms is provided between the bottom plate portion of the electronic device rack on which an electronic device can be mounted and the top plate portion provided above the bottom plate portion with a gap therebetween in the width direction. By contracting the pair of expanding and contracting mechanisms, the bottom plate portion and the top plate portion can be made to approach each other, and the electronic device rack can be switched to the contracted state.

In the step S22 of carrying the electronic device rack into an installation place, the electronic device rack in the contracted state is carried into the installation place of the electronic device rack.

In the step S23 of installing the electronic device rack in the installation place, the pair of expanding and contracting mechanisms is expanded to separate the bottom plate portion and the top plate portion from each other, and the electronic device rack is switched to the expanded state. The electronic device rack in the expanded is installed in the installation place.

With the method of installing the electronic device rack according to the example embodiments, it is possible to install an electronic device rack which can be easily carried in the installation place.

While the present disclosure has been described above in conjunction with some example embodiments, the present disclosure not limited to the example embodiments. The configurations or details of the present disclosure can be modified in various forms which can be understood by those skilled in the art within the scope of the present disclosure. Each example embodiment can be appropriately combined with other example embodiments.

According to the example aspects, it is possible to easily carry the electronic device rack into an installation place.

Some or all of the aforementioned example embodiments can also be described as in the following supplementary notes, but the present disclosure is not thereto.

### (Supplementary Note 1)

An electronic device rack including:
a bottom plate portion;
a top plate portion spaced apart from the bottom plate portion in a vertical direction;
a pair of expanders between the bottom plate portion and the top plate portion, the pair of expanders being spaced apart from each other in a width direction, each expander being configured to individually expand in the vertical direction to be in an expanded state; and
a constraint portion provided between the bottom plate portion and the top plate portion and configured to constrain the pair of expanders in the expanded state.

### (Supplementary Note 2)

The electronic device rack according to Supplementary note 1,
wherein the constraint portion includes constraint portions, and
wherein each constraint portion includes:
   a plate-shaped member having an upper end and a lower end, the plate-shaped member being rotatable around one of the upper end and the lower end as an axis, the axis extending in a longitudinal direction crossing the vertical direction and the width direction; and
   a fixing portion configured to fix the plate-shaped member in a state where a plate surface of the plate-shaped member is along the vertical direction.

### (Supplementary Note 3)

The electronic device rack according to Supplementary note 2,
wherein the plate-shaped member includes a first plate-shaped member and a second plate-shaped member which are provided side by side in the vertical direction, and
wherein the fixing portion is configured to connect the first plate-shaped member and the second plate-shaped member to each other.

### (Supplementary Note 4)

The electronic device rack according to Supplementary note 2 or 3,
wherein the plate-shaped member includes a first plate-shaped member at a first end in the width direction and a second plate-shaped member at a second end in the width direction, and
wherein, in a state where the first plate-shaped member and the second plate-shaped member are switched to be along a plane crossing the vertical direction, the fixing portion connects the first plate-shaped member and the second plate-shaped member to each other.

### (Supplementary Note 5)

The electronic device rack according to any one of Supplementary notes 2 to 4,
wherein the plate-shaped member includes a first plate-shaped member and a second plate-shaped member which are provided side by side in the vertical direction, and
wherein the fixing portion includes a connection pin and an insertion hole, the connection pin protruding toward the second plate-shaped member at one of the upper end and the lower end of the first plate-shaped member, the insertion hole being configured such that the connection pin is inserted into the insertion hole.

### (Supplementary Note 6)

The electronic device rack according to Supplementary note 5,
wherein the connection pin includes a pair of connection pins at both ends in the longitudinal direction of the first plate-shaped member, and
wherein the insertion hole includes a pair of insertion holes provided at both ends in the longitudinal direction of the second plate-shaped member.

### (Supplementary Note 7)

The electronic device rack according to any one of Supplementary notes 1 to 6,
wherein the constraint portions are provided inside of the pair of expanders in the width direction.

### (Supplementary Note 8)

The electronic device rack according to any one of Supplementary notes 1 to 7,
wherein each expander includes:
   a first support member extending in the longitudinal direction,
   a second support member capable of being spaced apart from the first support member in the vertical direction and extending in the longitudinal direction;
   a first link member including: a first end supported by the first support member to be rotatable; and a second end supported by the first support member to be slidable in the longitudinal direction; and
   a second link member including: a third end supported by the second support member to be rotatable; and a fourth end supported by the second support member to be slidable in the longitudinal direction.

### (Supplementary Note 9)

The electronic device rack according to Supplementary note 8,
wherein the one of the upper end and the lower end of the first plate-shaped member is supported by the first support member to be rotatable around the axis.

### (Supplementary Note 10)

The electronic device rack according to any one of Supplementary notes 1 to 9,
wherein the plate-shaped member includes a support portion configured to support an electronic instrument or a mount member on which an electronic instrument is mounted.

### (Supplementary Note 11)

The electronic device rack according to any one of Supplementary notes 1 to 10,
wherein each expander being configured to individually contract in the vertical direction to be in an contracted state, and
wherein the pair of expanders are configured to converge on the inside of an area in which the top plate portion and the bottom plate portion overlap as seen from above in the contracted state.

### (Supplementary Note 12)

An electronic device unit including:
the electronic device rack according to any one of Supplementary notes 1 to 11; and
an electronic instrument that is mounted in the electronic device rack.

### (Supplementary Note 13)

A method of installing an electronic device rack, the method including:
switching an electronic device rack to a contracted state by contracting a pair of expanders between a bottom plate portion and a top plate portion of the electronic device rack to make the bottom plate portion and the top plate portion approach each other, the electronic device rack being configured such that an electronic instrument is mounted in the electronic device rack, the pair of expanders being spaced apart from each other in a width direction, the top plate portion being spaced apart from the bottom plate portion in a vertical direction;
carrying the electronic device rack in the contracted state into an installation place of the electronic device rack; and
switching the electronic device rack to an expanded state by expanding the pair of expanders to separate the bottom plate portion and the top plate portion from each other to install the electronic device rack in the installation place.

Some or all of the configurations according to Supplementary notes 2 to 11 which are dependent on Supplementary note 1 can be applied to Supplementary note 13 with the same dependency as Supplementary notes 2 to 11. In addition to Supplementary note 1 and Supplementary note 13, some or all of the configurations according to the supplementary notes can be similarly applied to various electronic device racks, electronic device units, and methods of installing electronic device racks without departing from the example embodiments.

What is claimed is:

1. An electronic device rack comprising:
a bottom plate portion;
a top plate portion spaced apart from the bottom plate portion in a vertical direction;
a pair of expanders between the bottom plate portion and the top plate portion, the pair of expanders being spaced apart from each other in a width direction, each expander being configured to individually expand in the vertical direction to be in an expanded state; and
a constraint portion provided between the bottom plate portion and the top plate portion and configured to constrain the pair of expanders in the expanded state.

2. The electronic device rack according to claim 1,
wherein the constraint portion includes constraint portions, and
wherein each constraint portion includes:
a plate-shaped member having an upper end and a lower end, the plate-shaped member being rotatable around one of the upper end and the lower end as an axis, the axis extending in a longitudinal direction crossing the vertical direction and the width direction; and
a fixing portion configured to fix the plate-shaped member in a state where a plate surface of the plate-shaped member is along the vertical direction.

3. The electronic device rack according to claim 2,
wherein the plate-shaped member includes a first plate-shaped member and a second plate-shaped member which are provided side by side in the vertical direction, and
wherein the fixing portion is configured to connect the first plate-shaped member and the second plate-shaped member to each other.

4. The electronic device rack according to claim 2,
wherein the plate-shaped member includes a first plate-shaped member at a first end in the width direction and a second plate-shaped member at a second end in the width direction, and
wherein, in a state where the first plate-shaped member and the second plate-shaped member are switched to be along a plane crossing the vertical direction, the fixing portion connects the first plate-shaped member and the second plate-shaped member to each other.

5. The electronic device rack according to claim 2,
wherein the plate-shaped member includes a first plate-shaped member and a second plate-shaped member which are provided side by side in the vertical direction, and
wherein the fixing portion includes a connection pin and an insertion hole, the connection pin protruding toward the second plate-shaped member at one of the upper end and the lower end of the first plate-shaped member, the insertion hole being configured such that the connection pin is inserted into the insertion hole.

6. The electronic device rack according to claim 5,
wherein the connection pin includes a pair of connection pins at both ends in the longitudinal direction of the first plate-shaped member, and
wherein the insertion hole includes a pair of insertion holes provided at both ends in the longitudinal direction of the second plate-shaped member.

7. The electronic device rack according to claim 2,
wherein the constraint portions are provided inside of the pair of expanders in the width direction.

8. The electronic device rack according to claim 2,
wherein each expander includes:
a first support member extending in the longitudinal direction,
a second support member capable of being spaced apart from the first support member in the vertical direction and extending in the longitudinal direction;
a first link member including: a first end supported by the first support member to be rotatable; and a second end supported by the first support member to be slidable in the longitudinal direction; and
a second link member including: a third end supported by the second support member to be rotatable; and a fourth end supported by the second support member to be slidable in the longitudinal direction.

9. The electronic device rack according to claim 8,
wherein the one of the upper end and the lower end of the first plate-shaped member is supported by the first support member to be rotatable around the axis.

10. The electronic device rack according to claim 2,
wherein the plate-shaped member includes a support portion configured to support an electronic instrument or a mount member on which an electronic instrument is mounted.

11. The electronic device rack according to claim 1,
wherein each expander being configured to individually contract in the vertical direction to be in an contracted state, and
wherein the pair of expanders are configured to converge on the inside of an area in which the top plate portion and the bottom plate portion overlap as seen from above in the contracted state.

12. An electronic device unit comprising:
the electronic device rack according to claim 1; and
an electronic instrument that is mounted in the electronic device rack.

13. A method of installing an electronic device rack, the method comprising:
switching an electronic device rack to a contracted state by contracting a pair of expanders between a bottom plate portion and a top plate portion of the electronic device rack to make the bottom plate portion and the top plate portion approach each other, the electronic device rack being configured such that an electronic instrument is mounted in the electronic device rack, the pair of expanders being spaced apart from each other in a width direction, the top plate portion being spaced apart from the bottom plate portion in a vertical direction;
carrying the electronic device rack in the contracted state into an installation place of the electronic device rack; and
switching the electronic device rack to an expanded state by expanding the pair of expanders to separate the bottom plate portion and the top plate portion from each other to install the electronic device rack in the installation place
